(19) United States
(12) Patent Application Publication
(10) Pub. No.: US 2013/0052369 A1
(43) Pub. Date: Feb. 28, 2013

(54) PLASMA REACTOR

(71) Applicants: Aurel Salabas, Gams (CH); Abed al hay Taha, Chur (CH); Devendra Chaudhary, Oberschan (CH); Markus Klindworth, Sargans (CH); Christoph Ellert, Sion (CH)

(72) Inventors: Aurel Salabas, Gams (CH); Abed al hay Taha, Chur (CH); Devendra Chaudhary, Oberschan (CH); Markus Klindworth, Sargans (CH); Christoph Ellert, Sion (CH)

(73) Assignee: OERLIKON SOLAR AG, TRUEBBACH, Truebbach (CH)

(21) Appl. No.: 13/695,500

(22) PCT Filed: Apr. 29, 2011
(86) PCT No.: PCT/EP2011/056820

§ 371 Date: Oct. 31, 2012

Related U.S. Application Data
(60) Provisional application No. 61/331,887, filed on May 6, 2010.

(51) Int. Cl. C23C 16/50

(52) U.S. Cl. 427/569; 118/723 R; 118/723 E

(57) ABSTRACT

A plasma reactor with a recipient (33) and an electrode (38) has two exhaust openings (34, 35) spaced apart in a close proximity to the electrode (38). A flow diverter body (37) in the space of the reactor (33) between the periphery (313) of the electrode (3a) and the exhaust openings (35, 34) diverts the exhaust effect of the exhaust openings (35, 34) to avoid combined exhausting effect to become effective in the reactor space adjacent to the addressed periphery (313).

The invention relates generally to a plasma reactor. In particular, the reactor is suitable for (capacitively coupled) plasma enhanced chemical vapor deposition (PECVD) of thin films on large area substrates. More specific, the system allows deposition of a large variety of photovoltaic silicon thin films.

### BACKGROUND OF THE INVENTION

PECVD technology uses plasma processing equipment to perform thin film deposition. In general, the energy from an external power generator—often radio-frequency (RF) 13.56 Hz or more—is coupled either capacitively or inductively to a precursor gas (or gas mixture) fed to via an arrangement of gas inlets and enclosed in a reaction chamber (plasma box or plasma reactor).

The simplest capacitively coupled parallel plate plasma reactor arrangement contains in the vacuum recipient as a plasma arrangement generating a plasma in the vacuum recipient, two essentially flat, plate shaped electrodes accommodated within a closed reaction chamber in the vacuum recipient plus the arrangement of gas inlets and an gas exhaust arrangement. Typically, a first of the parallel plate electrodes is driven at frequencies in the MHz range (13.56 MHz—the standard industrial frequency or, more preferably, harmonics of said value), while the other one is grounded. To ensure that the reactor operates in a pure capacitive mode, its external circuit includes a blocking capacitor having negligible impedance at the driving frequency. This is a general valid configuration, but the apparatus or reactor can be easily adapted to perform a variety of plasma assisted treatments, like surface hardening by ion implantation, plasma assisted etching or thin film deposition. This design is widely used in microelectronics, for liquid crystal displays (LCD) and photovoltaics.

Over the years the above described configuration has been constantly developed to meet demands formulated mainly in microelectronics and LCD industry, and has reached a complexity which transform PECVD in a powerful and well established method. Its precision is recognized and appreciated in Si-based thin film photovoltaics, where PECVD plays again the central role. This key position of PECVD technology is associated with important cost. Any progress and advance of the equipment performance impacts considerably the costs and benefits. Assuming that a PECVD system performs 10% faster than before and the PECVD cost per workpiece thus decrease by 1 euro, then, through the tact-time, the overall impact in fab-scale can be a factor 2-4 higher. Specifically in the field of thin film silicon solar cells, any increase of the deposition rate in a PECVD apparatus or reactor lowers the cost of respective solar panels and decreases the unit cost of electricity obtained from PECVD based photovoltaic panels. In order to realize the benefits of solar energy at production cost level and to become competitive with traditional fossil energy sources it is clear that the combination of high deposition rates and good quality layers is mandatory. For this reason, worldwide intense research and engineering activities point to low cost and high performance photovoltaic PECVD equipment.

A prerequisite for any PECVD equipment wanting to be competitive in the market is the ability to deposit in a fast manner uniform and high quality films over large area substrates. Possibilities of a scale-up of laboratory machines by only changing extensive discharge parameters like gas fluxes and RF power are very limited. A successful scale-up is definitely linked to the manufacturer's ability to control complex physical aspects with and within an efficient mechanical design. A constant innovative input is necessary to overcome physical phenomena linked to RF excitation frequency, substrate size, RF power distribution or heat dissipation within a reaction chamber. Reliable and effective mechanical structures are necessary to ensure a proper distribution of reactive gases or an accurate loading/unloading system of substrates. Unwanted effects—like those caused by reactor chamber discontinuity or edges—have to be eliminated or substantially reduced.

### PROBLEMS KNOWN IN THE ART

To design and engineer plasma reactor with a focus on simplicity and increased performance is a considerable challenge. Often the work can be simplified by tuning a reactor's configuration to fit specific applications or processes. The development of a multi-functional platform which goes beyond customer specifications and meets a long list of requirements has to face several engineering problems and to solve sometimes contradictory physical issues.

Most of the problems reflect a complex interaction between four major poles: i) the equipment performance, ii) the substrate dimensions, iii) the characteristics of the processes that have to be accommodated and iv) operation and maintenance of the system.

U.S. Pat. No. 4,798,739 introduced the Plasma Box (“Boxes within box”) concept which allows efficient substrate load/unload sequences to and from an isothermal reactor. Further experience is accumulated in EP 1 953 794 A1, where specific problems of Plasma Boxes with large dimensions have been solved. In order to ensure an optimal gas distribution while preserving a trouble free electrical configuration, several innovative elements have been specified in U.S. Pat. No. 6,502,530. Film uniformity becomes an issue at higher RF excitation frequencies and large substrate dimensions. U.S. Pat. No. 6,228,438 B1 proposes a corrective layer that compensates for electromagnetic effects and/or process non-uniformities.

as a basis for the present invention a series of topics in the existing concepts have been identified, which demand for further improvement. In the following, a Prior Art design and its deficiencies are discussed with referring to FIG. 1 which schematically shows an example of a prior art plasma reactor.

A plasma reactor of the parallel-plate-type comprises, as an outer enclosure, a reactor bottom wall 116, a reactor top wall 110 and side walls 111 and 112. Load- and unload facilities as well as a substrate with a respective substrate holder is not shown in the figure.

Sidewalls 111 and/or 112 exhibit gas exhaust openings 17, 18 respectively. Pumps as well as external gas-piping are not shown in the figure. Within the recipient a top electrode 113 and a bottom electrode 114 are provided, the latter may also serve as substrate holder or pedestal. Both top and bottom electrodes are operatively connectable to a RF power source (not shown). During operation of the reactor a distributed plasma is ignited in the gap or reaction space between top electrode 113 and bottom electrode 114, thus establishing a plasma zone 115. In order to improve the isothermal properties of this reactor type as well as to improve the plasma confinement, exhaust grids 15 and 19 are provided.

“Behind” the top electrode 113, averted from the plasma zone 115, a gas distribution space 116 is provided. Working gases are fed from outside sources (not shown) into the gas distribution space 116. Grids 11, 12, 13 arranged therein act as voltage divider and gas distribution means. In order to compensate for edge effects in this reactor design a gap 14 allows for a surplus of working gases to be distributed to the peripheral area of plasma zone 115.

1. In today's layout of PECVD production systems, dedicated reactors for amorphous and micro/nanocrystalline silicon (μc-Si) deposition are common. However, having such process-dedicated machines has multiple, undesired implications. In a known arrangement with 10 parallel-run a-Si reactors a failure of two a-Si reactors results in the system operating at 80% capacity. The production capacity can remain above 93% if a more versatile plasma reactor or plasma box is adopted, in other words, if an a-Si reactor can easily be switched to μc-Si mode and vice versa. In such case, the reactor increases flexibility and reduces redundancy and dependencies. Maintenance and service as well as supply chain and stocks are simplified. The central and major advantage for any operator of such a system is definitely the production time.

2. Customer's and product requirements tend to constantly become more demanding. For a certain process, deviations of film thickness and/or crystallinity degree should be minimized. In particular, major deviations from the optimal crystallinity degree need to be overcome, especially along the substrate diagonal for rectangular substrates.

3. Gas and power consumption have to be further optimized. It is known to those skilled in the art, that PECVD of silicon based micro-crystalline layers is associated with dusty plasma regimes. In dusty regimes, a considerable amount of SiH₄ and RF power is lost in dust generation. Consequently less RF power is available to ensure the necessary Si-crystallinity and thus amorphous regions may appear in layers deposited. To compensate these losses, normally more RF power is supplied to the reactor from the beginning.

4. In Prior Art reactor designs reactor pumping grid(s) 15, 19 have been used as an additional way to improve deposition rate and film uniformity (through plasma confinement). However, several deficiencies can also be attributed to those grids: Electrostatic effects, unfavorable RF grounding affecting local plasma properties and, in consequence, also the film uniformity. Since the gas is pumped out or exhausted “along” the largest substrate dimension i.e. along the edges of a rectangular substrate, the substrate area affected by film non-uniformities can be considerable. If the local perturbations are extending only over 5 cm from the substrate edge toward the center, the affected area may already be about 9% of substrate surface. Edge effects (telegraph effect, bad grounding, pumping superposition etc.) can be pronounced and able to affect up to 20% of substrate surface. There are several ways to correct and compensate these effects.

5. Further grids—floating and screening grids 11, 12, 13 have been used to capacitively divide the potential across the gap between top electrode 113 and reactor top 110 (gas distribution space 116) and thus to eliminate spurious plasmas in this space. Although important, this requirement seems to be not so critical for certain photovoltaic processes that are currently executed by the machine. Simplifications are nevertheless possible.

The aforementioned issues, resulting from the necessity to improve performance and capabilities have led to the new plasma reactor or plasma box design according to this invention.

It is an object of the present invention to provide a plasma reactor and manufacturing method, by which the homogeneity of plasma treatment effect upon the surface of a substrate to be treated is improved thereby maintaining deposition efficiency with respect to electric power and gas consumption with respect to prior art reactors as have been exemplified with the help of FIG. 1

This is accomplished according to the present invention by a plasma reactor comprising a vacuum recipient, an arrangement of gas inlets to the vacuum recipient, a plasma arrangement generating a plasma in the vacuum recipient, a substrate holder within the vacuum recipient and an exhaust arrangement adjacent to a wall of the plasma recipient for gas to be removed from the plasma recipient and distant from the arrangement of gas inlets and from the substrate holder. The exhaust arrangement comprises at least one exhaust opening through the wall and at least one gas flow diverter body conceived to divert at least a part of flow of the gas to be removed from the vacuum recipient before entering the exhaust opening.

The addressed object is further resolved by the method for manufacturing a vacuum processed substrate comprising providing a substrate in an evacuated vacuum recipient, generating a distributed plasma discharge along a surface of the substrate, inletting a gas distributed into the distributed plasma discharge and removing gas from the distributed plasma discharge through at least one exhaust opening in the vacuum recipient, further comprising controlling distribution of gas flow from the plasma discharge towards and into the at least one exhaust opening by selectively tailoring the spatial distribution of exhausting effect of the gas exhaust opening by at least one flow blocking diverter body adjacent to and distant from the at least one exhaust opening.

The invention will now be further described with the help of examples, wherefrom further embodiments of the plasma reactor and of the method of manufacturing according to the present invention will become apparent. Reference is made to the accompanying figures. These figures show:

### BRIEF DESCRIPTION OF THE DRAWINGS

FIG. 1: Schematically and simplified a cross sectional view of a Prior Art plasma reactor;

FIG. 2: In a representation in analogy to that of FIG. 1 a cross-sectional view of a PECVD reactor according to one embodiment of the invention;

FIG. 3: A schematic representation of an embodiment of a gas flow diverter body as provided in the plasma reactor according to the present invention and as exploited by the method according to the present invention;

FIG. 4: schematically different possible shapes of a gas flow diverter body as of FIG. 2 or 3;

FIG. 5: Schematically and simplified a top view on a further embodiment of a plasma reactor according to the present invention, which, in cross sectional view may look as shown in the FIG. 2 and wherein the gas flow diverter body as addressed in context with FIGS. 3 and 4 may be provided.

FIG. 6: Schematically representations in analogy to that of FIG. 2 of further embodiments of flow diverter bodies in reactors according to the invention.

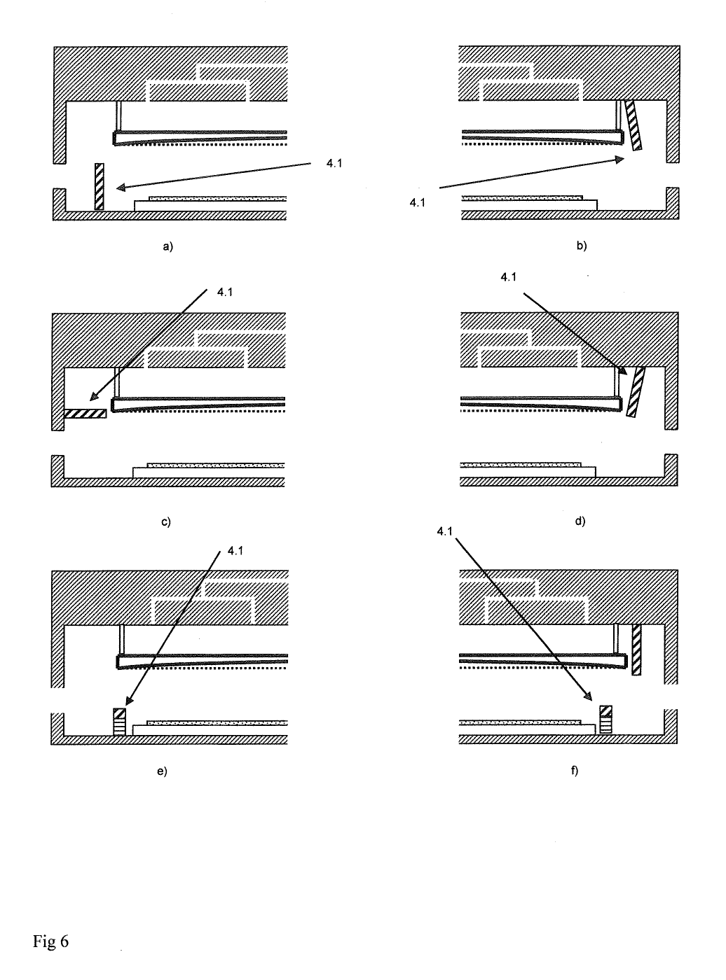

The plasma reactor according to the present invention and to perform the method according to the invention e.g. for performing at least PECVD processes in it comprises, in a recipient established by a reactor top wall 21, reactor sidewalls 23, 24 and a reactor bottom wall 22, an electrode 25 and, a substrate holder 27 for a substrate 26. The reactor bottom wall 22 or the substrate holder acts as counter electrode to electrode 25. At least one exhaust opening, preferably at least two 210, 29 are provided in the side walls 24 and 23 and in the vicinity of and distant from the electrode 25 and/or of substrate holder 27 as shown in FIG. 6, with, in operation, substrate 26. A gas flow diverter body 218 is arranged in close proximity to the electrode 25 in a manner that the negative effects of uncontrolled flow of gas being pumped out of the exhaust opening 210 are at least substantially reduced. The gas flow diverter body 218 can exhibit, as shown, a bar-shaped profile especially a shape and geometric arrangement according to design rules addressed below. The gas flow diverter body 218 is preferably of metal, but may also be of a dielectric material or of a combination of both, metal and dielectric. The gas flow diverter body of metal can be set on an electric reference potential, especially on ground potential or can be mounted electrically insulated with respect to all metal parts within the reactor operated on a defined electric potential and thus electrically floatingly.

The plasma reactor as of FIG. 2 is especially suited for PECVD of silicon thin films on substrates 26 equal to or larger than 1.4 m². Doped/un-doped, amorphous or micro-crystalline photovoltaic thin films with properties and growth rates relevant for mass production can be deposited. According to the invention, the physical-chemical properties of the obtained films enjoy an improved uniformity across the entire substrate area. The invention takes into account many physical phenomena characteristic to capacitively coupled gas discharges at RF frequencies above 10 MHz.

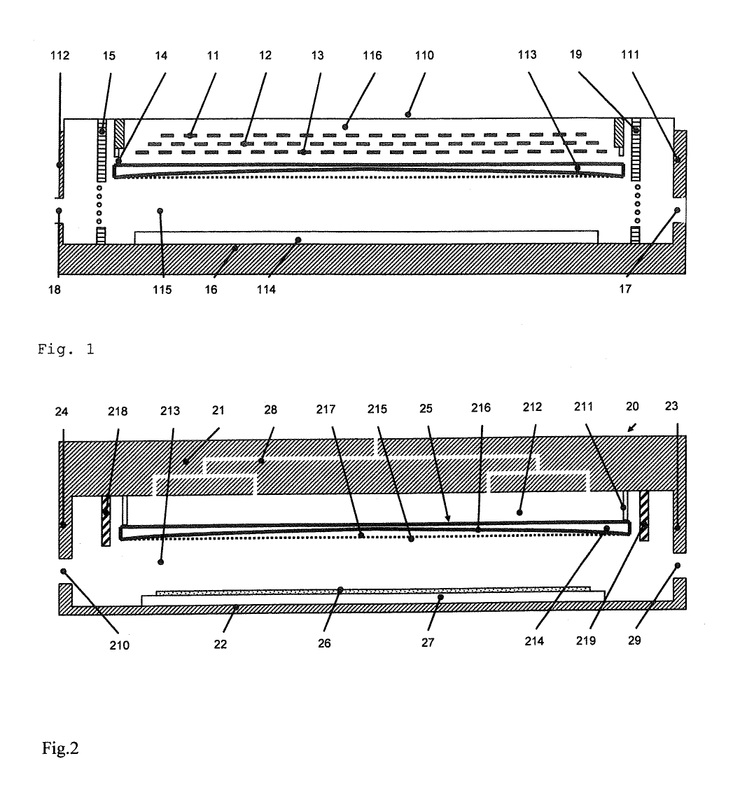

The plasma reactor of the invention with the gas flow diverter body 218 is based on a few key observations made on prior art plasma reactors as of FIG. 1 for deposition of micro-crystalline silicon:
Pumping grids 15, 19 rather deteriorate film uniformity. The reasons are multiple.
Removing the pumping grids however will establish a new gas flow distribution and different electrical properties in the reactor.
Prior art gap 14 directing peripheral gas to the edge regions of the plasma zone 115 enhances losses in gas and RF power.
According to the plasma reactor as exemplified in FIG. 2 floating and screening grids 11 to 13 can be reduced or avoided. This results in a significant construction simplification of the reactor.
In the prior art plasma reactor as of FIG. 1 standing wave effects due to reflection of RF waves inside the plasma reactor are strong, especially along the larger dimensions of a substrate, thus on a square substrate along the substrate diagonal. This has implications on the design of a corrective capacitive layer.
To an important extent, and for a considerable substrate surface, relevant film properties can nevertheless be tuned by an adequate design of the electrode shape defining a corrective layer.

Additionally to the object as addressed above the plasma reactor and manufacturing method according to the present invention allow the execution of various plasma assisted processes with increased performance thereby especially PECVD processes.

Turning back to the embodiment of a plasma reactor according to the invention of FIG. 2 in more details, the plasma reactor 20 comprises the reactor top wall 21 and the reactor bottom wall 22 as well as the sidewalls 23, 24, all preferably electrically grounded. An RF frequency signal at 13.56 MHz or higher, preferably harmonics of such frequency, is supplied to the RF electrode 25 accommodated in the plasma reactor 20. The RF electrode 25 comprises a conductive electrode body 214 and a dielectric plate 215. The surface 216 of the electrode body 214 facing the planar dielectric plate 215 exhibits a curved, concave shape such that a volume 217 is enclosed in between.

The connection to an RF power source as well as the mount of the RF electrode 25 are not shown in FIG. 2. The substrate 26 is placed on the substrate holder 27 by a load/unload mechanism not shown. The interspace between electrode 25 and the substrate 26 and/or substrate holder 27 is called plasma zone or reaction volume 213.

A gas distribution arrangement 28 with an arrangement of gas inlets to the recipient of the plasma reactor is based on a cascaded, bifurcated piping ensuring a homogeneous distribution of process gas(es) or gas mixture(s) over a significant area of the internal surface of reactor top wall 21 and into a gas distribution volume 212. The electrode 25 is perforated in order to allow gases to pass from gas distribution volume 212 into plasma zone 213. Exhaust gases are evacuated through gas exhaust openings 29 and/or 210. An insulating spacer 211 separates the RF electrode 25 from the top wall 21. The height of the gas distribution volume 212 is defined by the condition that no spurious/parasitic discharges shall occur between the surface averted from plasma zone 213 of electrode 25 and the internal surface of the reactor top wall 21. The planar dielectric plate 215 is preferably made from ceramics and is also provided with gas openings such that the gas is evenly distributed into the plasma zone 213. As was addressed, the volume 217 is defined by the concave surface of the electrode body 216 and the opposing surface of dielectric plate 215. In FIG. 2, a gas flow diverter body 218 controls flow of gas to be removed from the recipient of the plasma reactor by and through exhaust opening 210, whereas a further gas flow diverter body 219 controls flow of gas to be removed from the recipient of the plasma reactor by and through the further exhaust opening 29. In the embodiment of FIG. 2 both gas flow diverter bodies 218 and 219 are mounted to the reactor top wall 21 and project up to and adjacent to an area of the periphery of the electrode 25 which is closest to the respective exhaust opening 29 and 210. Different mounts and positionings of gas flow diverter bodies will become apparent from the following description.

It will become apparent to those skilled in the art that there are many alterations in detail and scale that may be made upon the flow diverter bodies exemplified in the description without departing from the spirit and scope of the present invention. For example, the gap between electrode 25 and the substrate 26, corresponding to thickness of the plasma zone 213 has usually a value between 3 mm and 5 cm but can be generically chosen so that an optimum uniformity of films deposited on the substrate 26 is achieved.

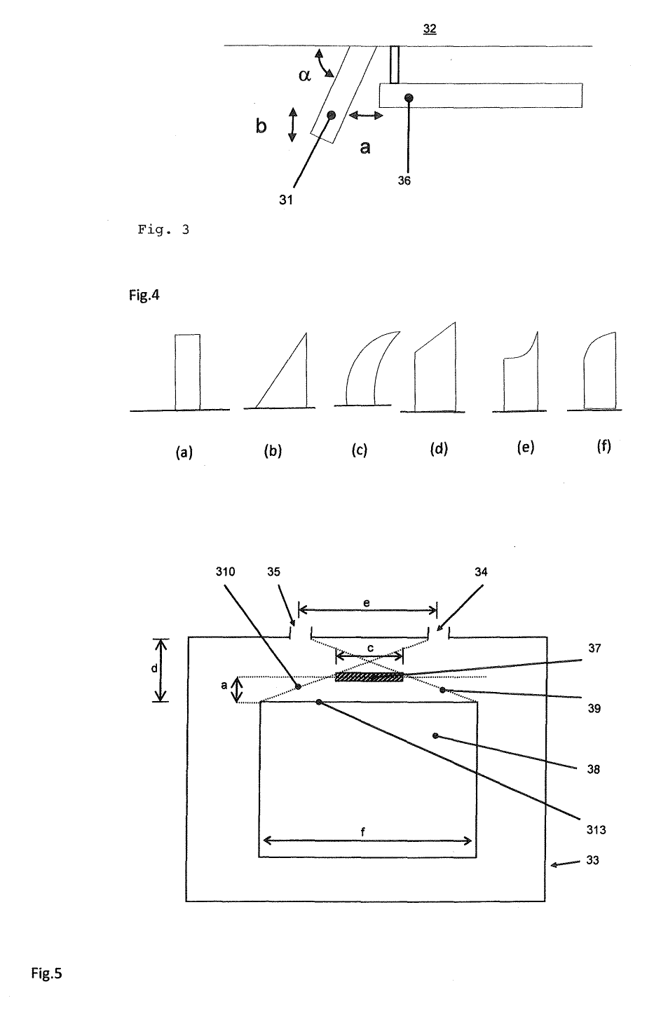

FIG. 3 illustrates possible variations of a gas flow diverter body e.g. according to the one or both of the gas flow diverter bodies 218, 219 provided in the embodiment of FIG. 2 and also for gas flow diverter bodies which will be addressed in the following description. The size and the positioning of the gas flow diverter body addressed in FIG. 3 by reference number 31 can be defined by a few parameters: As shown in FIG. 3 a distance “a” between the edge of an electrode arrangement 36, which accords with the respective edge of electrode 25 in the embodiment of FIG. 2 and the gas flow diverter body 31, which in fact is a gas flow corrector, amounts to 2 mm-4 mm (both limits included), amounts preferable 3 mm. The distance “b” amounts to 3-6 mm (both limits included), preferably 5 mm. Thereby the distance “b” represents the effective distance between the edge of the electrode 36 and the edge of the gas flow diverter body 31, in other words the projection of the gas flow diverter body over edge of electrode 36.

The angle α may be chosen between 70-110° (both limits included), with a preferred value of 90°. The angle is defined as shown in FIG. 3 between a reactor wall 32 along which and adjacent to which the electrode 36 is provided and the gas flow diverter body 31. Generically the gas flow diverter body as provided in a plasma reactor according to the invention, as one part of an exhaust arrangement, additionally comprising the exhaust opening, ensures a “gas retention” or gas flow diverting effect so as to correct the film thickness and additionally corrects a locally incoupled power to the plasma so as e.g. to improve crystallinity content of a deposited layer upon the substrate 26.

In FIG. 4 alternative cross-sectional shapes for the gas flow diverter body 31 are proposed: This shape can be rectangular (a), triangular (b), bent tooth shape (c) or exhibit an essentially rectangular shape which is, at the narrow side, rounded down ((f), chamfered (e) or truncated (d). The edge may thus have planar, convex or concave shape.

In the embodiment of FIG. 5 the recipient 33 of the plasma reactor is square box shaped. The exhaust arrangement comprises two side by side exhaust openings 35 and 34 in one of the side walls of the square shaped recipient. In cross sectional view this embodiment may appear same as the embodiment of FIG. 2 with the exception of the exhaust arrangement or as one of the FIG. 6 embodiments.

The dimension “c” of e.g. about 40 cm in FIG. 5 is defined by the pumping superposition at and adjacent to the one side wall of recipient 33 construed to treat a substrate e.g. of 1.1×1.3 m². The gas flow diverter body 37 is made from a metal, such as of Al, and can be either grounded e.g. electrically connected to the reactor top or bottom wall as of 21 or 22 according to FIG. 2 or may be electrically insulated with respect to metal members of and/or in the recipient which are operated on a specific electric potential as e.g. on ground potential.

The effect of “pumping superposition” can be explained with the aid of FIG. 5 showing the interior of a recipient 33 in top view with an electrode 38 and the gas flow diverter body 37. The substrate is not shown; however, since electrode 38 and a substrate are similar in shape, comparable in size and in close relationship within the vacuum system as may be seen for the substrate 26 and the electrode 25 of FIG. 2 the statements below apply to the electrode as well as to the substrate carrier and substrate accordingly.

For large area reactors 33 under vacuum a single exhaust opening often is not sufficient, since the pumping impact is not homogeneously effective upon the whole treatment relevant volume in the recipient. An essentially homogeneous pumping effect can only be realized for a volume that is within a certain spatial angle range extending from the exhaust opening. If one arranges two exhaust openings 34 and 35 spaced apart but effective substantially upon the same volume in the recipient 33 and in a close proximity to the electrode 38, e. g. essentially in the plane of such electrode, the angle ranges mentioned above of both openings will overlap along a certain spatial area of the volume in the reactor. In this overlap volume area gases present in the plasma zone “see” both exhaust openings 35 and 34 and the pumping effect and thus gas flow will be more pronounced in this overlap volume area than in adjacent volume areas.

In this case the gas flow diverter body 37 has to be shaped and arranged relative to the electrode 38 generically to avoid double exhaust effect in the recipient especially close to the exhaust opening, where the exhaust effect is pronounced. The length of the gas flow diverter body 37 has to be chosen such that, dependent on the distance “e” of openings 34 and 35 as well as of distance “d” between openings 34 and 35 and the nearest electrode edge or periphery area, 313, it blocks or shades that area, where the effective pumping impact by the two exhaust openings is considerably increased.

This relationship can be determined geometrically as indicated in FIG. 5: The lengthwise extension of the gas flow diverter body 37 is the distance between the two intersections of lines 39 and 310 with a line parallel with electrode edge 313 at the distance “a”.

If the distance “e” between the two exhaust openings amounts to 60 cm and the distance “d” between the electrode edge 313 and the wall of the recipient 33 is close to 7 cm, the length “c” of the gas flow diverter body 37 will amount to about 40 cm. Variations of the geometry, thereby keeping the relations between c, d, and e essentially constant will allow to scale the inventive gas flow diverter body 37 up and down. For an exhaust arrangement with three exhaust openings e.g. two gas flow diverter bodies may be arranged following the instructions above, calculating the respective values in pairs.

FIG. 6 shows, based on the embodiment of the plasma reactor as shown in FIG. 2 alternative configurations for the installation of a gas flow diverter body 41, according to the gas diverter body 31 of FIG. 3, 218 of FIG. 2 or 37 of FIG. 5. In general, the selection of the appropriate embodiment from FIGS. 2, 3, 4,5 and 6 is based on the particularities of the process to be executed by the plasma reactor. In particular, the process pressure plays a major role. For example, intermediate pressure regimes of 3-12 mbar may require an extension of the gas flow diverter body length up to the full substrate length and an appropriate embodiment such as those illustrated in FIG. 6(e,f). In FIG. 6(e) an electrically “floating” gas flow diverter body is installed on reactor bottom and combination of grounded and insulated gas flow diverter bodies is shown in FIG. 6(f). Independently of configuration the location, size and shape of a gas flow diverter body have to fulfill the requirement that the information about the location of gas exhaust opening(s) 35, 34 should “vanish” all along the substrate edge i. e. pumping superposition's effect should disappear. Further and additionally the ohmic plasma heating in the vicinity of the gas flow diverter body should ensure the necessary gas dissociation rate and properties of the deposited film.

Deposited silicon thin films obtained with a reactor according to the invention have been analyzed by means of ellipsometry, Raman spectroscopy, Fourier Transform Infrared and Fourier Transform Photocurrent Spectroscopy. These techniques have confirmed that high quality photovoltaic layers can be obtained at significant higher deposition rates. Table 1 (below) compares deposition rate, thickness uniformity and crystallinity content of amorphous and micro-crystalline photovoltaic silicon films obtained with a system according to the present invention and earlier versions of plasma reactors or plasma boxes as of FIG. 1. In summary the measures described above considerably improve the control over degree of crystallinity of the Si-layer, reduces thickness non-uniformities and ensures higher deposition rates across the whole substrate area. Simultaneously, previous deficiencies have been eliminated or substantially reduced.

| | |
|---|---|
| This | |
| invention | Prior Art |

| Characteristics | a-Si | μc-Si | a-Si | μc-Si |
|---|---|---|---|---|
| Deposition rate | 3-7 | 6-12 | 3-4 | 5.5 |
| (\acute{Å}s⁻¹) | | | | |
| Thickness | 12-20 | <12 | 20-30 | <20 |
| uniformity (%) | | | | |
| Crystallinity | — | 45-65 | — | 20-80 |
| content (%) | | | | |

As apparent from the above description the present invention is

A)a plasma reactor comprising a vacuum recipient, an arrangement of gas inlets to said vacuum recipient, a plasma arrangement generating a plasma in the vacuum recipient, a substrate holder within the vacuum recipient and an exhaust arrangement adjacent to a wall of the vacuum recipient for gas to be removed from the vacuum recipient and distant from the arrangement of gas inlets and from the substrate holder, the exhaust arrangement comprising at least one exhaust opening through the wall and at least one gas flow diverter body conceived to divert at least a part of flow of the addressed gas to be removed from the vacuum recipient before entering the exhaust opening.

In one embodiment B) of the reactor as addressed under A) said recipient is box shaped comprising a top and a bottom wall and a side wall, said at least one gas exhaust arrangement being provided adjacent said side wall, said plasma arrangement generating said plasma comprising an electrode with an electrode surface extending along one of said top and bottom walls and having an electrode surface periphery distant from said side wall, said flow diverter body being conceived to selectively divert flow of said gas to be removed having passed an area of said electrode surface periphery closest to said exhaust arrangement.

In one embodiment C) of the reactor as addressed under B)

said recipient is square-box shaped and said electrode surface is square shaped.

In one embodiment D) of the reactor as addressed under B)

said flow diverter body is bar-shaped, arranged alongside and distant from said electrode surface periphery closest to said exhaust opening and distant from said exhaust opening in a space of said recipient between said electrode surface periphery closest to said exhaust opening and said exhaust opening.

In one embodiment E) of the reactor as addressed under D)

said recipient is square-box shaped and said electrode surface is square shaped.

In one embodiment F) of the reactor as addressed under A)

said recipient is box shaped comprising a top and a bottom wall and a side wall, said at least one gas exhaust arrangement being provided adjacent said side wall, said substrate holder extending along one of said top and of said bottom walls and having a substrate holder periphery distant from said side wall, said flow diverter body being conceived to selectively divert flow of said gas to be removed having passed an area of said substrate holder periphery closest to said exhaust arrangement.

In one embodiment G) of the reactor as addressed under F)

said recipient is square-box shaped and said substrate holder is square shaped.

In one embodiment H) of the reactor as addressed under F)

said flow diverter body is bar-shaped, arranged alongside and distant from said substrate holder periphery closest to said exhaust opening and distant from said exhaust opening in a space of said recipient between said substrate holder periphery closest to said exhaust opening and said exhaust opening.

In one embodiment I) of the reactor as addressed under H)

said recipient is square-box shaped and said substrate holder is square shaped.

In one embodiment J) of the reactor as addressed under B)

said substrate holder extends along the other of said top and of said bottom walls and has a substrate holder periphery distant from said side wall, said gas exhaust arrangement comprising a second of said flow diverter bodies being conceived to selectively divert flow of said gas to be removed having passed an area of said substrate holder periphery closest to said exhaust arrangement.

In one embodiment K) of the reactor as addressed under J)

said recipient is square-box shaped and said substrate holder and said electrode surface are square shaped.

In one embodiment L) of the reactor as addressed under J)

said second flow diverter body is bar-shaped, arranged alongside and distant from said substrate holder periphery closest to said exhaust opening and distant from said exhaust opening in a space of said recipient between said substrate holder periphery closest to said exhaust opening and said exhaust opening.

In one embodiment M) of the reactor as addressed under L) said recipient is square-box shaped and said substrate holder and said electrode surface are square shaped.

In one embodiment N) of the reactor as addressed under A)

said exhaust arrangement comprises at least two of said exhaust openings and said at least one flow diverter body is conceived to divert flow of said gas to be removed substantially exclusively towards one of said at least two exhaust openings or towards the other of said at least two exhaust openings.

In one embodiment O) of the reactor as addressed under N)

said recipient is box shaped comprising a top and a bottom wall and a side wall, said at least one gas exhaust arrangement being provided adjacent said side wall, said arrangement generating said plasma comprising an electrode with an electrode surface extending along one of said top and bottom walls and having an electrode surface periphery distant from said side wall, said flow diverter body being conceived to selectively divert flow of said gas to be removed having passed an area of said electrode surface periphery closest to said exhaust arrangement.

In one embodiment P) of the reactor as addressed under O)

said recipient is square-box shaped and said electrode surface is square shaped and wherein said exhaust arrangement is provided adjacent to one of the four side walls of the square-box.

In one embodiment Q) of the reactor as addressed under O)

said flow diverter body is bar-shaped, arranged alongside and distant from said electrode surface periphery closest to said exhaust opening and distant from said exhaust opening in a space of said recipient between said electrode surface periphery closest to said exhaust opening and said exhaust opening.

In one embodiment R) of the reactor as addressed under Q)

said recipient is square-box shaped and said electrode surface is square shaped and wherein said exhaust arrangement is provided adjacent to one of the four side walls of the square-box.

In one embodiment S) of the reactor as addressed under N)

said recipient is box shaped comprising a top and a bottom wall and a side wall, said at least one gas exhaust arrangement being provided adjacent said side wall, said substrate holder extending along one of said top and of said bottom walls and having a substrate holder periphery distant from said side wall, said flow diverter body being conceived to selectively divert flow of said gas to be removed having passed an area of said periphery closest to said exhaust arrangement.

In one embodiment T) of the reactor as addressed under S)

said recipient is square-box shaped and said substrate holder is square shaped and wherein said exhaust arrangement is provided adjacent to one of the four side walls of the square-box.

In one embodiment U) of the reactor as addressed under S)

said flow diverter body is bar-shaped, arranged alongside and distant from said substrate holder periphery closest to said exhaust opening and distant from said exhaust opening in a space of said recipient between said substrate holder periphery closest to said exhaust opening and said exhaust opening.

In one embodiment V) of the reactor as addressed under U)

said recipient is square-box shaped and said substrate holder is square shaped and wherein said exhaust arrangement is provided adjacent to one of the four side walls of the square-box.

In one embodiment W) of the reactor as addressed under O)

said substrate holder extends along the other of said top and of said bottom walls and has a substrate holder periphery distant from said side wall, said gas exhaust arrangement comprising a second of said flow diverter bodies being conceived to selectively divert flow of said gas to be removed having passed an area of said substrate holder periphery closest to said exhaust arrangement.

In one embodiment X) of the reactor as addressed under W)

said recipient is square-box shaped and said substrate holder is square shaped and wherein said exhaust arrangement is provided adjacent to one of the four side walls of the square-box.

In one embodiment Y) of the reactor as addressed under W)

said second flow diverter body is bar-shaped, arranged alongside and distant from said substrate holder periphery closest to said exhaust opening and distant from said exhaust opening in a space of said recipient between said substrate holder periphery closest to said exhaust opening and said exhaust opening.

In one embodiment Z) of the reactor as addressed under Y) said recipient is square-box shaped and said substrate holder is square shaped and wherein said exhaust arrangement is provided adjacent to one of the four side walls of the square-box.

In one embodiment Z1) of the reactor as addressed under one of the embodiments D), E), L), M), O), R), Y) or Z)

said bar-shaped diverter body projects by a distance “a” over said electrode surface for which there is valid

2 mm≦a≦4 mm

and wherein said flow diverter body is distant from said surface by a distance “b” for which there is valid

3 mm≦b≦6 mm.

In one embodiment Z2) of the reactor as addressed under Z1) the end of said bar shaped diverter body projecting over said electrode surface is one of plane, convexly bent, concavely bent.

In one embodiment Z3) of the reactor as addressed under one of the embodiments H), I), L), M), U), V), Y) or Z)

said bar-shaped diverter body projects by a distance “a” over said substrate holder periphery for which there is valid

2 mm≦a≦4 mm

and wherein said flow diverter body is distant from said substrate holder periphery by a distance “b” for which there is valid

3 mm≦b≦6 mm.

In one embodiment Z4) of the reactor as addressed under Z3) the end of said bar shaped diverter body projecting over said electrode surface is one of plane, convexly bent, concavely bent.

In one embodiment Z5) of the reactor as addressed under any one of the embodiments A) to Z4) said at least one gas diverter body is of a metal and is electrically connected to a metal part of said reactor or is electrically isolated from any further metal part of said reactor.

What is claimed is:

1. A plasma reactor comprising a vacuum recipient, an arrangement of gas inlets to said vacuum recipient, a plasma arrangement generating a plasma in said vacuum recipient, a substrate holder within said vacuum recipient and an exhaust arrangement adjacent to a wall of said vacuum recipient for gas to be removed from said vacuum recipient and distant from said arrangement of gas inlets and from said substrate holder, said exhaust arrangement comprising at least one exhaust opening through said wall and at least one gas flow diverter body conceived to divert at least a part of flow of said gas to be removed from said vacuum recipient before entering said exhaust opening.

2. The reactor of claim 1, wherein said recipient is box shaped comprising a top and a bottom wall and a side wall, said at least one gas exhaust arrangement being provided adjacent said side wall, said plasma arrangement generating said plasma comprising an electrode with an electrode surface extending along one of said top and bottom walls and having an electrode surface periphery distant from said side wall, said flow diverter body being conceived to selectively divert flow of said gas to be removed having passed an area of said electrode surface periphery closest to said exhaust arrangement.

3. The reactor of claim 2, wherein said recipient is square-box shaped and said electrode surface is square shaped.

4. The reactor of claim 2, wherein said flow diverter body is bar-shaped, arranged alongside and distant from said electrode surface periphery closest to said exhaust opening and distant from said exhaust opening in a space of said recipient between said electrode surface periphery closest to said exhaust opening and said exhaust opening.

5. The reactor of claim 1, wherein said recipient is box shaped comprising a top and a bottom wall and a side wall, said at least one gas exhaust arrangement being provided adjacent said side wall, said substrate holder extending along one of said top and of said bottom walls and having a substrate holder periphery distant from said side wall, said flow diverter body being conceived to selectively divert flow of said gas to be removed having passed an area of said substrate holder periphery closest to said exhaust arrangement.

6. The reactor of claim 5, wherein said recipient is square-box shaped and said substrate holder is square shaped.

7. The reactor of claim 5, wherein said flow diverter body is bar-shaped, arranged alongside and distant from said substrate holder periphery closest to said exhaust opening and distant from said exhaust opening in a space of said recipient between said substrate holder periphery closest to said exhaust opening and said exhaust opening.

8. The reactor of claim 1, wherein said exhaust arrangement comprises at least two of said exhaust openings and said at least one flow diverter body is conceived to divert flow of said gas to be removed substantially exclusively towards one of said at least two exhaust openings or towards the other of said at least two exhaust openings.

9. The reactor of claim 8, wherein said recipient is box shaped comprising a top and a bottom wall and a side wall, said at least one gas exhaust arrangement being provided adjacent said side wall, said arrangement generating said plasma comprising an electrode with an electrode surface extending along one of said top and bottom walls and having an electrode surface periphery distant from said side wall, said flow diverter body being conceived to selectively divert flow of said gas to be removed having passed an area of said electrode surface periphery closest to said exhaust arrangement.

10. The reactor of claim 9, wherein said recipient is square-box shaped and said electrode surface is square shaped and wherein said exhaust arrangement is provided adjacent to one of the four side walls of the square-box.

11. The reactor of claim 9, wherein said flow diverter body is bar-shaped, arranged alongside and distant from said electrode surface periphery closest to said exhaust opening and distant from said exhaust opening in a space of said recipient between said electrode surface periphery closest to said exhaust opening and said exhaust opening.

12. The reactor of claim 8, wherein said recipient is box shaped comprising a top and a bottom wall and a side wall, said at least one gas exhaust arrangement being provided adjacent said side wall, said substrate holder extending along one of said top and of said bottom walls and having a substrate holder periphery distant from said side wall, said flow diverter body being conceived to selectively divert flow of said gas to be removed having passed an area of said periphery closest to said exhaust arrangement.

13. The reactor of claim 12, wherein said flow diverter body is bar-shaped, arranged alongside and distant from said substrate holder periphery closest to said exhaust opening and distant from said exhaust opening in a space of said recipient between said substrate holder periphery closest to said exhaust opening and said exhaust opening.

14. The reactor of one of claim 1, wherein said at least one gas diverter body is of a metal and is electrically connected to a metal part of said reactor or is electrically isolated from any further metal part of said reactor.

15. A method for manufacturing a vacuum processed substrate comprising providing a substrate in an evacuated vacuum recipient, generating a distributed plasma discharge along a surface of said substrate, inletting a gas distributed into said plasma discharge and removing gas from said plasma discharge through at least one exhaust opening in said vacuum recipient, further comprising controlling distribution of gas flow from said plasma discharge towards and into said at least one exhaust opening by selectively tailoring the spatial distribution of exhausting effect of said gas exhaust opening by at least one flow blocking diverter body adjacent to and distant from said exhaust opening.
